(19) United States
(12) Patent Application Publication
(10) Pub. No.: US 2019/0181319 A1
(43) Pub. Date: Jun. 13, 2019

(54) THERMOELECTRIC CONVERSION ELEMENT, AND METHOD FOR MANUFACTURING A THERMOELECTRIC CONVERSION ELEMENT

(71) Applicant: KABUSHIKI KAISHA TOSHIBA, Minato-ku (JP)

(72) Inventors: Atsushi WADA, Kawasaki (JP); Rei HASEGAWA, Yokohama (JP)

(73) Assignee: KABUSHIKI KAISHA TOSHIBA, Minato-ku (JP)

(21) Appl. No.: 16/108,470

(22) Filed: Aug. 22, 2018

(30) Foreign Application Priority Data
Dec. 8, 2017 (JP) 2017-236522

(51) Int. Cl. H01L 35/24; H01L 35/34; H01L 35/28; H01L 35/02

(52) U.S. Cl. CPC H01L 35/24; H01L 35/34; H01L 51/0055; H01L 35/02; H01L 35/28

(57) ABSTRACT

Certain embodiments provide a thermoelectric conversion element includes: a thermoelectric conversion layer configure to contain an organic material formed on a substrate, and the organic material doped a metallic oxide; a first electrode configure to be provided on the thermoelectric conversion layer; and a second electrode configure to be provided on the thermoelectric conversion layer being apart from the first electrode.

### CROSS-REFERENCE TO RELATED APPLICATION

This application is based upon and claims the benefit of priority from Japanese Patent Application No. 2017-236522 filed on Dec. 8, 2017, the entire contents of which are incorporated herein by reference.

### FIELD

Embodiments described herein relate generally to a thermoelectric conversion element and a method for manufacturing a thermoelectric conversion element.

### BACKGROUND

Thermoelectric conversion elements that convert a large quantity of unutilized thermal energy present in an environment into electric energy to generate electric power include a thermoelectric conversion layer that generates electromotive force using a temperature difference between two thermal sources that have different temperatures from each other. The thermoelectric conversion layer maintains both ends at different temperatures from each other, thereby generating the electromotive force. Such an action and effect of the thermoelectric conversion layer is called a Seebeck effect. For example, the thermoelectric conversion layer is formed of an organic semiconductor material such as C8-BTBT (C8-benzothienobenzothiophene) that is a thiophene-based polycyclic aromatic compound.

Organic materials have a lower thermal conductivity than a thermal conductivity of metallic materials etc. Hence, when both ends of an organic material are respectively connected to two thermal sources that have different temperatures from each other, the temperatures of the two thermal sources are not likely to be uniform, and thus a large temperature difference is caused between both ends of the organic material. The larger the temperature difference is, the greater the electromotive force generated by the Seebeck effect becomes. Accordingly, thermoelectric conversion elements increase the electromotive force by utilizing the organic material as the thermoelectric conversion layer.

Moreover, using a flexible organic material to the thermoelectric conversion layer enables a production of a flexible organic thermoelectric conversion element that deforms in accordance with the shape of the thermal source. Furthermore, since organic thermoelectric conversion elements do not utilize high-cost materials such as a rare metal, the production costs are reduced.

However, organic materials have a problem of a lower electrical conductivity than an electrical conductivity of metallic materials etc. A power factor (PF) that indicates the thermoelectric conversion ability of converting thermal energy to electric energy is expressed by a product of the power of a Seebeck coefficient of a conductive material by the electrical conductivity, and thus when the electrical conductivity is low, the power factor decreases.

### BRIEF DESCRIPTION OF THE DRAWINGS

FIG. 1 is a cross-sectional view illustrating a thermoelectric conversion element according to an embodiment;

FIG. 2 is a diagram illustrating a relationship in energy level between an organic material and orbitals of an organic material and metallic oxides;

FIG. 3 is a diagram illustrating a characteristic curve that indicates a relationship among an oxidation level of a thermoelectric conversion layer to which PEDOT:TOS is applied, the Seebeck coefficient, and a power factor; and

FIG. 4 is a diagram illustrating how the thermoelectric conversion element is utilized.

### DETAILED DESCRIPTION

An embodiment will be described below with reference to the figures. An orthogonal coordinate system that has an X-axis, a Y-axis, and a Z-axis which orthogonal to each other is applied for the description.

A thermoelectric conversion element converts thermal energy to electric energy. As indexes that indicate the characteristics of the thermoelectric conversion element, a power factor PF (W/mK²) expressed by the following (formula 1), a performance index Z (ρWm⁻¹K⁻²) expressed by the following (formula 2), and a dimensionless performance index ZT (μWm⁻¹K⁻¹) expressed by the following (formula 3) are adopted. Note that S indicates a Seebeck coefficient (V/K), σ indicates an electrical conductivity (S/cm; where S is Siemens), T indicates an absolute temperature (K), and k indicates a thermal conductivity (W/mK).

PF=S²σ (Formula 1)

Z=S²σ/k (Formula 2)

ZT=S²σK/k (Formula 3)

The Seebeck coefficient S in the above (formula 1) to (formula 3) is a proportional constant in the relational expression between the temperature difference of both ends of the thermoelectric conversion element and the magnitude of the electromotive force. The magnitude (V) of the electromotive force is expressed by the following (formula 4) using the Seebeck coefficient S and the temperature difference (ΔT) of both ends of the thermoelectric conversion element.

V=SΔT (Formula 4)

The Seebeck coefficient S varies depending on the carrier concentration of a substance. In general, the Seebeck coefficient S decreases together with an increase in the carrier concentration.

The performance index Z is an index that indicates an energy conversion efficiency when thermal energy is converted to electric energy. The greater the performance index Z of the thermoelectric conversion element is, the greater the acquired electromotive force is. The dimensionless performance index ZT is an index that indicates an energy conversion efficiency at a specific temperature. The power factor PF indicates the thermoelectric conversion ability of the thermoelectric conversion element. The greater the power factor PF of the thermoelectric conversion element is, the higher the performance index Z is. In general, the thermoelectric conversion element is considered as practical as the thermoelectric conversion element when the dimensionless performance index ZT is equal to or greater than 1.

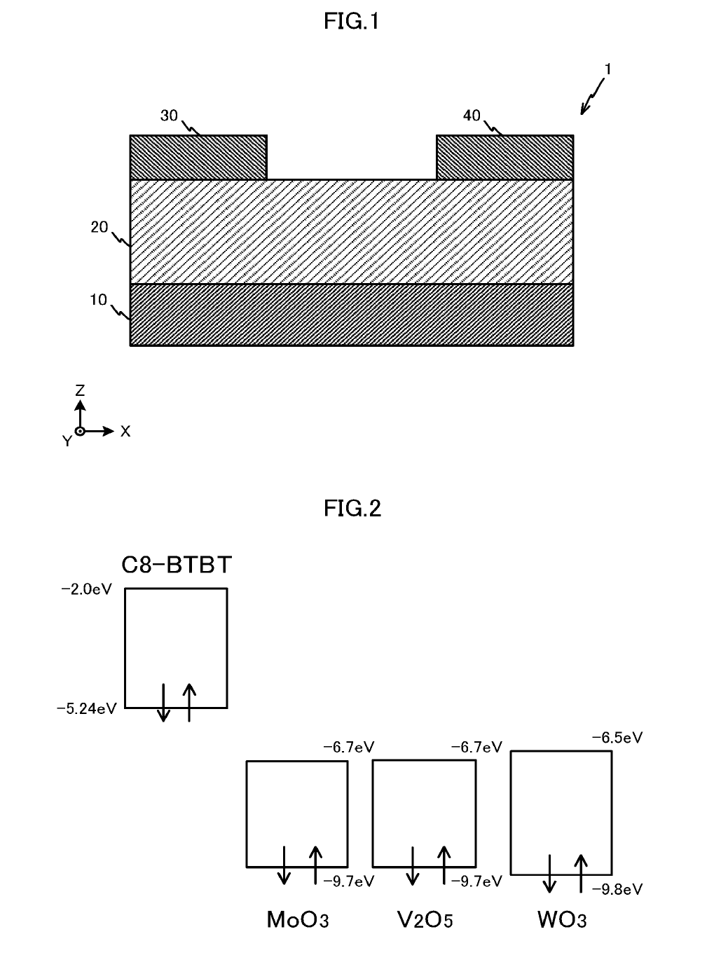

FIG. 1 is a cross-sectional view illustrating a thermoelectric conversion element 1. The thermoelectric conversion element 1 includes a substrate 10, a thermoelectric conversion layer 20, a first electrode 30, and a second electrode 40.

The substrate 10 is, for example, a glass substrate. Moreover, the substrate 10 may be a flexible substrate with a high elasticity such as a plastic film.

As illustrated in FIG. 1, the thermoelectric conversion layer 20 is formed on the surface of the substrate 10 at the +Z-side. The thickness of the thermoelectric conversion layer 20 in the Z-axis direction is substantially 250 nm. The thermoelectric conversion layer 20 is formed by an organic material doped with a metallic oxide.

The organic material contained in the thermoelectric conversion layer 20 is a conjugated organic material. The conjugated organic material is preferably a polycyclic aromatic compound that has a basic skeleton which is polycyclic aromatic hydrocarbon with hetero aromatic. The polycyclic aromatic compound contained in the thermoelectric conversion layer 20 is, more preferably, a thiophene-based polycyclic aromatic compound that has a high carrier mobility.

As for the conjugated organic material such as polycyclic aromatic ring, the greater the number of aromatic-series to be condensed is, the higher the carrier mobility becomes. However, as for the conjugated organic material such as polycyclic aromatic ring, the greater the number of aromatic series to be condensed increases, the further the stability relative to oxygen decreases. The polycyclic aromatic ring becomes stable relative to oxygen when combined with hetero aromatic. The carrier mobility increases when thiophene that is one of the hetero aromatic is combined with the polycyclic aromatic ring.

More specifically, the organic material contained in the thermoelectric conversion layer 20 is a thiophene-based polycyclic aromatic compound expressed by the following general expressions (1) and (2). The thiophene-based polycyclic aromatic compound expressed by the following general expressions (1) and (2) preferably have a molecular weight that is equal to or smaller than 1000.

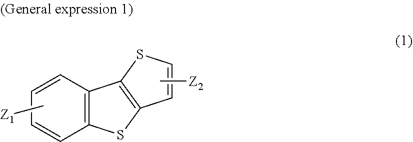

(In the above general expression (1), Z₁ and Z₂ represent aromatic hydrocarbon ring or aromatic heterocycle independent from each other.)

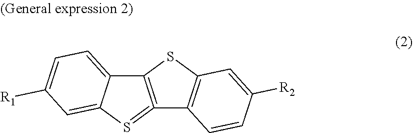

(In the above general expression (2), R1 and R2 are independent from each other. R₁ and R₂ represent hydrogen atom, alkyl group or substituent with alkyl group.)

In this embodiment, examples of alkyl groups are straight-chain alkyl group and branched-chain alkyl group. Examples of straight-chain alkyl groups are methyl group, ethyl group, propyl group, butyl group, pentyl group, hexyl group, heptyl group, octyl group, nonyl group, and decyl group, but are not limited to these according to the present disclosure.

Moreover, examples of branched-chain alkyl groups are isopropyl group, isobutyl group, isoamyl group, s-butyl group, t-butyl group, 2-methyl-butyl group, 2-methyl-hexyl group, 2-ethyl-hexyl group, 2-methyl-octyl group, 2-ethyl-octyl group, cyclo-pentyl group, and cyclohexyl group, but are not limited to these according to the present disclosure.

In this embodiment, examples of substituents that have alkyl group are alkyl group substituted by silyl-ethynyl group, alkyl group substituted by aryl group, alkyl group substituted by aromatic heterocycle group, alkyl group substituted by alkoxyl group, cyclo-alkoxyl group, and aryloxy group, alkyl group substituted by alkylthio group, cyclo-alkylthio group, and arylthio group, and alkyl group substituted by alkoxycarbonyl group, and aryl-oxy-carbonyl group, but are not limited to these according to the present disclosure.

In this embodiment, examples of aromatic hydrocarbon rings are phenyl, biphenyl, naphthalene, anthracene, tetracene, pentacene, hexacene, heptacene, acenaphthene, naphthacene, azulene, phenalene, benzanthracene, phenanthrene, and chrysene, but are not limited to these according to the present disclosure.

Moreover, in this embodiment, examples of aromatic heterocycles are furil, thiophene, thenyl, and pyridyl, but are not limited to these according to the present disclosure.

In this embodiment, examples of metallic oxides doped in the thermoelectric conversion layer are MoO₃ (molybdenum trioxide), V₂O₅ (vanadium pentoxide), and WO₃ (tungsten trioxide), but are not limited to these according to the present disclosure.

The carrier concentration of the thermoelectric conversion layer 20 increases by doping impurities that supply careers to the organic material that forms the thermoelectric conversion layer 20. Therefore, an electrical conductivity of the thermoelectric conversion layer 20 is improved.

In general, when the energy level at the Highest Occupied Molecular Orbital (HOMO) of an organic material is higher than the energy level of the Lowest Unoccupied Molecular Orbital (LUMO) of impurities, electrons of the organic material are insufficient and producing holes are generated, and thus the carrier concentration increases and the electrical conductivity of the organic material increases.

On the other hand, a Seebeck coefficient S of the thermoelectric conversion layer 20 decreases by doping the impurities that supply the careers to the organic material that forms the thermoelectric conversion layer 20.

The carrier concentration of the thermoelectric conversion layer 20 has a temperature dependency, and the higher the temperature of the thermoelectric conversion layer 20 is, the larger the carrier concentration becomes. When a temperature difference occurs between both ends of the thermoelectric conversion layer 20, a difference in carrier concentration occurs at both ends of the thermoelectric conversion layer 20, thus electromotive force is generated.

However, when the impurities that supply the careers to the organic material that forms the thermoelectric conversion layer 20 are doped and carrier concentration increases, a difference in carrier concentration between the high-temperature side of the thermoelectric conversion layer 20 and the low-temperature side thereof becomes relatively small. In this case, the electromotive force of the thermoelectric conversion layer 20 becomes small. Consequently, the Seebeck coefficient S of the thermoelectric conversion layer 20 which is a proportional constant between the temperature difference and the electromotive force decreases.

The conduction band of a metallic oxide has a large energy difference from the energy level at the HOMO of a thiophene-based polycyclic aromatic compound. In the case of the thermoelectric conversion layer 20 that contains thiophene-based polycyclic aromatic compound in which metallic oxide is doped, the metallic oxide becomes an acceptor that is an electron acceptor.

FIG. 2 is a diagram illustrating a relationship among orbitals of an organic material that is C8-BTBT (C8-benzothienobenzothiophene) and metallic oxides that are MoO₃, V₂O₅, and WO₃. As illustrated in FIG. 2, the conduction bands of the metallic oxides that are MoO₃, V₂O₅, and WO₃ have a large energy difference from the energy level at the HOMO of C8-BTBT that is a thiophene-based polycyclic aromatic compound.

For example, the energy level at the HOMO of the valence band of C8-BTBT is −5.24 eV. Moreover, the energy level at the LUMO of the conduction band of MoO₃ is −6.7 eV. The energy difference in energy level between the energy level at the conduction band of MoO₃ and the energy level at the HOMO of C8-BTBT is 1.46 eV.

Similarly, the energy difference between the conduction band of V₂O₅ and the energy level at the HOMO of C8-BTBT is 1.46 eV. Moreover, the energy difference in energy level between the conduction band of WO₃ and the energy level at the HOMO of C8-BTBT is 1.26 eV.

In the case of the thermoelectric conversion layer 20 that contains C8-BTBT in which MoO₃ is doped, MoO₃ becomes an acceptor that receives an electron from C8-BTBT. Next, a hole is generated in C8-BTBT, and thus the electrical conductivity improves.

In general, the energy band such as a conduction band of a substance has a variability of substantially 0.2 eV. Hence, the energy difference between the conduction band of the metallic oxide and the energy level at the HOMO of the organic material contained in the thermoelectric conversion layer 20 is preferably equal to or greater than 0.2 eV.

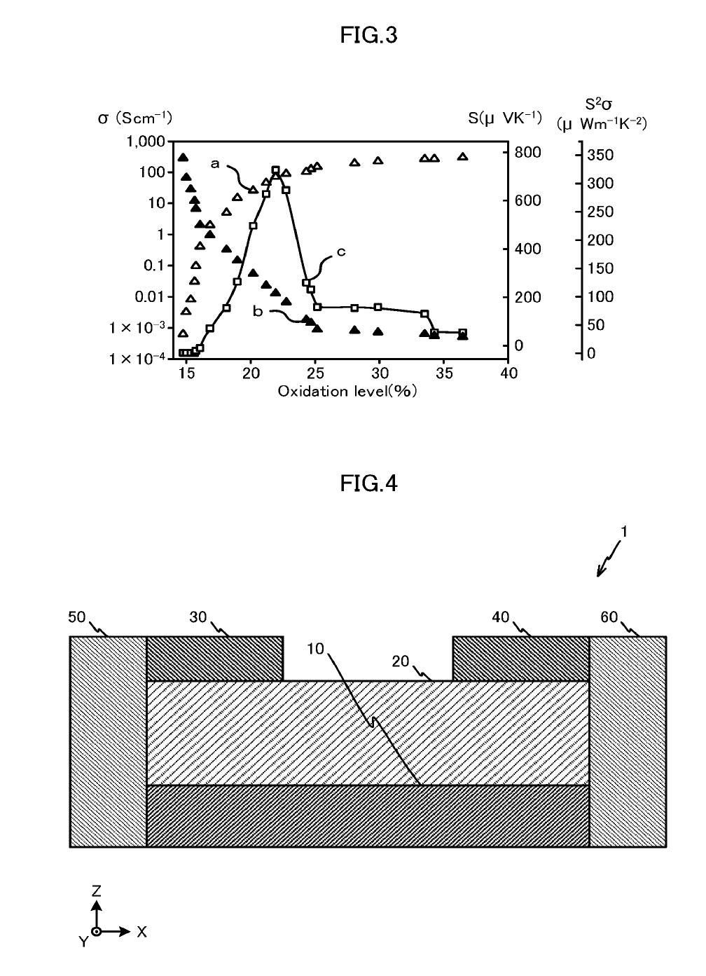

FIG. 3 is diagram illustrating a characteristic curve that indicates a relationship among an oxidation level of the thermoelectric conversion layer 20 to which PEDOT:TOS is applied, the Seebeck coefficient S, and the dimensionless performance index ZT. The material PEDOT:TOS is a mixed film in which TOS (Tosylate) is doped in PEDOT (poly(3,4-ethylene-dioxythiophene)) instead of the metallic oxide.

A characteristic curve a in FIG. 3 indicates a relationship between the oxidation level of the PEDOT:TOS and an electrical conductivity a of the PEDOT:TOS.

A characteristic curve b indicates a relationship between the oxidation level of the PEDOT:TOS and a Seebeck coefficient S of the PEDOT:TOS.

A characteristic curve c indicates a relationship between the oxidation level of the PEDOT:TOS and the power factor PF of the PEDOT:TOS.

The PEDOT is one of polythiophenes in which thiophene is condensed. Moreover, the TOS is one of sulfonate ester. In the PEDOT:TOS, the TOS is an acceptor and the electrons of thiophene rings that are a part of PEDOT become insufficient.

Sulfur that is contained in TOS, and sulfur that is contained in PEDOT show respective peaks at different energies in an X-ray-photoelectron-spectroscopy spectrum. Hence, the X-ray-photoelectron-spectroscopy spectrum of the PEDOT:TOS shows two peaks. The oxidation level of the PEDOT:TOS is acquired based on the ratio of the magnitudes of the two peaks of the X-ray-photoelectron-spectroscopy spectrum of the PEDOT:TOS.

Accordingly, the peak of the X-ray-photoelectron-spectroscopy spectrum of sulfur contained in the TOS is compared with the peak of the X-ray-photoelectron-spectroscopy spectrum of sulfur contained in the PEDOT.

Moreover, the larger the TOS is, the greater the magnitude of the peak volume of the X-ray-photoelectron-spectroscopy spectrum of sulfur contained in the TOS. The magnitude of the peak of sulfur contained in the PEDOT is constant regardless of the amount of the TOS.

Next, the ratio of the magnitude of the peak of the X-ray-photoelectron-spectroscopy spectrum of sulfur contained in the TOS with reference to the magnitude of the peak of sulfur contained in the PEDOT is the oxidation level of the PEDOT:TOS. Note that the term oxidation means to lose electrons, and the greater the oxidation level is, the more the holes are generated in the PEDOT, and the carrier concentration of the PEDOT:TOS becomes large.

As indicated by the characteristic curve a in FIG. 3, the greater the oxidation level of the PEDOT:TOS is, the more the electrical conductivity σ of the PEDOT:TOS improves. In contrast, as indicated by the characteristic curve b, the greater the oxidation level of the PEDOT:TOS is, the further the Seebeck coefficient S of the PEDOT:TOS decreases.

Consequently, as indicated by the characteristic curve c in FIG. 3, because of the balance between the Seebeck coefficient S and the electrical conductivity a, a peak is shown at the location where the oxidation level of the PEDOT:TOS is 23% in the characteristic curve c that indicates a relationship between the oxidation level of the PEDOT:TOS and the power factor PF.

The position of the peak in the characteristic curve c that indicates the relationship between the oxidation level and the power factor PF varies depending on the kind of the organic material and the kind of the impurities that supply the careers. Moreover, an oxidation level of the mixed film that contains the organic material in which the impurities that supply the careers are doped is proportional to the percent-by-mass concentration of the doped impurities.

Although not illustrated in the figure, the power factor PF of the thermoelectric conversion layer 20 that contains C8-BTBT in which MoO₃ is doped becomes the maximum when MoO₃ is substantially 3 percent by mass.

The first electrode 30 and the second electrode 40 are each a metal electrode which is formed on the surface of the thermoelectric conversion layer 20 at the +Z side, and which is formed of Au (gold). The first electrode 30 is a metal electrode in a thin-film shape that has the lengthwise direction parallel to the Y-axis direction.

The second electrode 40 is formed at the +X side relative to the first electrode 30. The second electrode 40 is a metal electrode in a thin-film shape that has the lengthwise direction parallel to the Y-axis direction.

In this embodiment, although the metal that forms the first electrode 30 and the second electrode 40 is Au, the present disclosure is not limited to this material. The first electrode 30 and the second electrode 40 is preferably formed of a metal that has a work function close to the energy level at the Highest Occupied Molecular Orbital (HOMO) of an organic material. The metal that has such a work function establishes an Ohmic contact with an organic material.

When the Ohmic contact is established between the organic material and the metal, an Ohm's law is achieved when a current flows from the organic material to the metal and also when the current flows from the metal to organic material.

In the case of a combination of the Au electrode with C8-BTBT that is a thiophene-based polycyclic aromatic compound, the Au electrode and C8-BTBT establish an Ohmic contact. The work function of Au is 5.1 eV, and the energy level at the HOMO of C8-BTBT that is a thiophene-based polyaromatic compound is 5.2 eV.

How the thermoelectric conversion element 1 according to this embodiment is utilized will be described below in detail.

FIG. 4 is a diagram illustrating how the thermoelectric conversion element 1 is utilized. As illustrated in FIG. 4, a high-temperature-side thermal source 50 and a low-temperature-side thermal source 60 that are thermal sources with different temperatures are joined with both side surfaces of the thermoelectric conversion element 1 in the X-axis direction, respectively.

The high-temperature-side thermal source 50 is connected to the surface of the thermoelectric conversion element 1 at the −X side. The high-temperature-side thermal source 50 has a higher temperature than a temperature of the thermoelectric conversion layer 20 of the thermoelectric conversion element 1. Hence, the temperature of the end of the thermoelectric conversion layer 20 at the −X side rises.

The low-temperature-side thermal source 60 is connected to the surface of the thermoelectric conversion element 1 at the +X side. The low-temperature-side thermal source 60 has a lower temperature than a temperature of the thermoelectric conversion layer 20 of the thermoelectric conversion element 1. Hence, the temperature of the end of the thermoelectric conversion layer 20 at the +X side decreases.

Consequently, the temperature gradient in the thermoelectric conversion layer 20 to which the high-temperature-side thermal source 50 and the low-temperature-side thermal source 60 are connected has a temperature decreasing from the end at the −X side to the end at the +X side.

The carrier concentration of the thermoelectric conversion layer 20 has a temperature dependency, the carrier concentration at the end of the thermoelectric conversion layer 20 at the −X side at which the temperature rises increases, and the carrier concentration at the end of the thermoelectric conversion layer 20 at the +X side at which the temperature falls decreases. Hence, the holes move to the end of the thermoelectric conversion layer 20 at the +X side from the end of the thermoelectric conversion layer 20 at the −X side. Consequently, in the thermoelectric conversion layer 20, the electromotive force that is proportional to the temperature difference between both ends of the thermoelectric conversion layer 20 in the X-axis direction occurs.

Next, a method of manufacturing of the thermoelectric conversion element 1 according to this embodiment will be described in detail.

The thermoelectric conversion element 1 according to this embodiment includes the thermoelectric conversion layer 20 which is formed on the substrate 10, and which contains C8-BTBT (C8-benzothienobenzothiophene) that is a thiophene-based polycyclic aromatic compound expressed by the following general expression (3) and in which MoO₃ (molybdenum trioxide) is doped, and the first electrode 30 and second electrode 40 each formed of Au (gold) that are formed on the thermoelectric conversion layer 20.

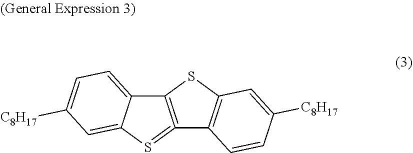

2] First, the substrate 10 is prepared. Next, after cleansing the substrate 10 by a surfactant, pure water, acetone, and isopropyl alcohol, UV ozone cleansing is performed on the cleansed substrate. Subsequently, the cleansed substrate 10 is fastened to a substrate holder in a vapor deposition chamber of a vapor deposition apparatus.

Next, C8-BTBT and MoO₃ (available from KOJUNDO chemical laboratory Co., Ltd, molybdenum trioxide (VI), purity: 99.99% and form: powder) are put in respective crucibles. C8-BTBT is sold at a market and sublimated and refined C8-BTBT substantially has the same physical properties.

The crucible in which C8-BTBT has been put, and the crucible in which MoO₃ has been put are placed in a vacuum vapor deposition chamber. The crucible is placed at a position that faces the substrate 10.

Next, the thermoelectric conversion layer 20 that contains C8-BTBT in which MoO₃ of substantially 3 percent-by-mass has been doped is formed on the substrate 10 by vacuum vapor deposition.

The thermoelectric conversion layer 20 that contains the organic material doped with metallic oxide, such as MoO₃ (molybdenum trioxide), V₂O₅ (vanadium pentoxide) or WO₃ (tungsten trioxide), is difficult to form a film by screen printing.

Since the metallic oxide is not likely to be dissolve in an organic solvent, an organic material and a metallic oxide are difficult to dissolve in an organic solvent. Hence, according to the screen printing that causes an organic material and a metallic oxide to be dissolved in an organic solvent to form a film, only the thermoelectric conversion layer 20 that has a quite small percent-by-mass concentration of the metallic oxide doped in the organic material is formed.

However, according to the vacuum vapor deposition that does not need the metallic oxide to be dissolved in the organic solvent, the thermoelectric conversion layer 20 is formed which has a large percent-by-mass concentration of the metallic oxide doped in the organic material.

Hence, according to a vacuum vapor deposition, the thermoelectric conversion layer 20 which is difficult to form by screen printing applying an organic solvent, and which contains an organic material that has a large percent-by-mass concentration of the doped metallic oxide, is formed.

As for V₂O₅ and WO₃, when subjected to vapor deposition by vacuum vapor deposition, some of V₁O₅ and WO₃ change properties due to heating. Hence, using MoO₃ as the metallic oxide is preferable.

Macromolecular organic materials that have a molecular weight exceeding 10,000 do not become a gas, thus having no evaporation temperature. Moreover, in general, the evaporation temperature of an organic material that is evaporated becomes high in proportion to the magnitude of the intermolecular force of the organic material. Furthermore, the intermolecular force of an organic material becomes large in proportion to the molecular weight of the organic material. Hence, the evaporation temperature of an organic material becomes high in proportion to the molecular weight of the organic material.

Accordingly, an organic material that has a larger molecular weight needs to be heated to a higher temperature when vapor deposition is performed. However, when the temperature becomes high, a part of the organic material is decomposed. Accordingly, the thiophene-based polycyclic aromatic compound applied as the organic material is preferably a low molecular material having a small molecular weight, and more preferably is a low molecular material having a molecular weight equal to or less than 1000 such as C8-BTBT.

The interior of the vapor deposition chamber of the vapor deposition apparatus is depressurized to a vacuum condition, and the crucibles placed in the vapor deposition apparatus are heated. Heated C8-BTBT and MoO₃ are evaporated, become gas molecules, and are dispersed within the vapor deposition chamber. C8-BTBT and MoO₃ dispersed within the vapor deposition chamber stick to the surface of the substrate 10 fastened to the substrate holder provided in the upper space of the vapor deposition chamber, and thus the thermoelectric conversion layer 20 that contains C8-BTBT doped with MoO₃ is formed.

The vapor deposition rate is controlled in such a way that the vapor deposition rate of C8-BTBT becomes 1 Å/sec, and the vapor deposition rate is further controlled in such a way that the vapor deposition rate of MoO₃ becomes 0.03 Å/sec. The vapor deposition rate of C8-BTBT and that of MoO₃ are controlled by measuring a film thickness using a quartz crystal film thickness gage. The control method of the vapor deposition rate using a quartz crystal film thickness gage is a well-known control method of the thickness of the thermoelectric conversion layer 20.

The percent-by-mass concentration of MoO₃ contained in the formed thermoelectric conversion layer 20 are calculated from the vapor deposition rate of C8-BTBT and the vapor deposition rate of MoO₃. When the vapor deposition rate of C8-BTBT is 1 Å/sec and the vapor deposition rate of MoO₃ is 0.03 Å/sec, the percent-by-mass concentration of MoO₃ contained in the formed thermoelectric conversion layer 20 is substantially 3 percent-by-mass concentration.

Next, the vapor deposition is performed until the thickness of the thermoelectric conversion layer 20 that contains C8-BTBT doped with MoO₃ becomes 250 nm.

Next, the first electrode 30 and the second electrode 40 are formed on the thermoelectric conversion layer 20 by electron beam vapor deposition.

Au (gold) is put into a metal container, and the metal container is placed in the vapor deposition chamber. The metal container in which Au (gold) has been put is located at a position that faces the substrate 10.

The metal container in which Au has been put is irradiated with electron beams. Au which is heated and evaporated by the electron beams is dispersed within the vapor deposition chamber, and is vapor-deposited on the surface of the thermoelectric conversion layer 20, and thus the electrodes are formed.

Vapor deposition is performed until the thickness of the AU electrode becomes 200 nm, and thus the first electrode 30 and the second electrode 40 that are each an Au electrode are formed on the thermoelectric conversion layer 20 as described above.

Eventually, the produced thermoelectric conversion element 1 is encapsulated. Under a nitrogen atmosphere, encapsulating of the thermoelectric conversion element 1 is performed by pasting glass substrates each having a moisture absorbent on the substrate 10 on which the thermoelectric conversion layer 20, the first electrode 30, and the second electrode 40 are formed, thereby encapsulating the substrate.

A thermoelectric conversion layer 20-1 as a conventional example will be evaluated below with reference to comparison examples that are a thermoelectric conversion layer 20-2 and a thermoelectric conversion layer 20-3.

Table 1 shows respective power factors PF, Seebeck coefficients S, and electrical conductivities a of the thermoelectric conversion layer 20-1 containing C8-BTBT (C8-benzothienobenzothiophene) doped with no MoO₃ (molybdenum trioxide), the thermoelectric conversion layer 20-2 containing PEDOT:PSS (styrene-sulfonic-acid polymer), and the thermoelectric conversion layer 20-3 containing Bi—Te. Note that the thermoelectric conversion layer 20-1 is formed by spin coating.

TABLE 1

| | Layer 20-1 | Layer 20-2 | Layer 20-3 |
|---|---|---|---|
| PF [W/mk²] | 7.6 × 10⁻⁸ | 4.7 × 10⁻⁴ | 4.0 × 10⁻³ |
| S [V/K] | 1.9 × 10⁻² | 7.2 × 10⁻⁵ | 2.0 × 10⁻⁴ |
| σ [S/cm] | 2.1 × 10⁻⁸ | 900 | 1000 |

As shown in table 1, the Seebeck coefficient S of the thermoelectric conversion layer 20-1 I larger than the Seebeck coefficient S of the thermoelectric conversion layer 20-2 and the thermoelectric conversion layer 20-3.

However, an electrical conductivity σ of the thermoelectric conversion layer 20-1 is quite smaller than the electrical conductivity σ of the thermoelectric conversion layer 20-2 and the thermoelectric conversion layer 20-3.

Hence, the power factor PF of the thermoelectric conversion layer 20-1 is quite smaller than the power factor PF of the thermoelectric conversion layer 20-2 and the thermoelectric conversion layer 20-3.

Next, the Seebeck coefficient S and the electrical conductivity σ of the thermoelectric conversion layer 20 according to this embodiment and containing C8-BTBT doped with MoO₃ of substantially 3 percent-by-mass were measured, and the power factor PF was calculated. As for the measurement of the Seebeck coefficient S and the electrical conductivity σ, a thermoelectric characteristic measuring apparatus (available from Advanced RIKO, Ltd., ZEM-3) was applied, and the measurement was carried out under a room temperature that was 25° C.

Table 2 shows respective power factors PF, Seebeck coefficients S and electrical conductivities a of the thermoelectric conversion layer 20 according to this embodiment and the thermoelectric conversion layer 20-1 as the conventional example.

TABLE 2

| | Layer 20-1 | Layer 20 |
|---|---|---|
| PF [W/mK²] | 7.6 × 10⁻⁸ | 1.5 × 10⁻⁶ |
| S [V/K] | 1.9 × 10⁻² | 5.4 × 10⁻⁴ |
| σ [S/cm] | 2.1 × 10⁻⁸ | 5.3 |

As shown in Table 2, the Seebeck coefficient S of the thermoelectric conversion layer 20 is smaller than the Seebeck coefficient S of the thermoelectric conversion layer 20-1.

However, the electrical conductivity σ of the thermoelectric conversion layer 20 is quite larger than the electrical conductivity σ of the thermoelectric conversion layer 20-1.

Consequently, the power factor PF of the thermoelectric conversion layer 20 is higher than the power factor PF of the thermoelectric conversion layer 20-1.

As described above, according to this embodiment, the electrical conductivity of the organic material applied to the thermoelectric conversion layer is improvable.

Although the embodiment has been described above, the present disclosure is not limited to the above embodiment. For example, in the above embodiment, as for the organic material, the polycyclic aromatic compound that has a basic skeleton which is polycyclic aromatic hydrocarbon with hetero aromatic is applied. The present disclosure is not limited to this case, and for example, polycyclic aromatic hydrocarbon such as pentacene is also applicable as the organic material.

In the above embodiment, the thiophene-based polycyclic aromatic compound is applied as the polycyclic aromatic compound that has a basic skeleton which is polycyclic aromatic hydrocarbon with hetero aromatic. The present disclosure is not limited to this case, and a polycyclic aromatic compound that has a basic skeleton which is a polycyclic aromatic hydrocarbon with furan and pyridine is also applicable.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A thermoelectric conversion element comprising:
a thermoelectric conversion layer configure to contain an organic material formed on a substrate, and the organic material is doped with a metallic oxide;
a first electrode configure to be provided on the thermoelectric conversion layer; and
a second electrode configure to be provided on the thermoelectric conversion layer being apart from the first electrode.

2. The thermoelectric conversion element according to claim 1, wherein
the metallic oxide is molybdenum trioxide.

3. The thermoelectric conversion element according to claim 2, wherein
the molybdenum trioxide is contained by 3 percent-by-mass.

4. The thermoelectric conversion element according to claim 1, wherein
the organic material is a thiophene-based organic material.

5. The thermoelectric conversion element according to claim 4, wherein
the thiophene-based organic material is C8-benzothienobenzothiophene.

6. The thermoelectric conversion element according to claim 1, wherein
the organic material has a molecular weight of equal to or smaller than 1000.

7. The thermoelectric conversion element according to claim 1, wherein
an energy difference between an energy level at a Highest Occupied Molecular Orbital of the organic material and a conduction band of the metallic oxide is equal to or greater than 0.2 eV.

8. The thermoelectric conversion element according to claim 1, wherein
the first electrode and the second electrode are each a metal electrode formed of Au.

9. The thermoelectric conversion element according to claim 1, wherein
the organic material is pentacene.

10. The thermoelectric conversion element according to claim 1, wherein
the metallic oxide is vanadium pentoxide or tungsten trioxide.

11. A method of manufacturing of a thermoelectric conversion element, comprising:
forming a thermoelectric conversion layer in which an organic material and a metallic oxide are mixed by vapor-depositing the organic material and the metallic oxide on a substrate; and
forming a first electrode and a second electrode apart from each other on the thermoelectric conversion layer.

12. The method according to claim 11, wherein
the metallic oxide is molybdenum trioxide.

13. The method according to claim 12, wherein
the molybdenum trioxide is contained by 3 percent-by-mass.

14. The method according to claim 11, wherein
the organic material is a thiophene-based organic material.

15. The method according to claim 14, wherein
the thiophene-based organic material is C8-benzothienobenzothiophene.

16. The method according to claim 11, wherein
the organic material has a molecular weight of equal to or smaller than 1000.

17. The method according to claim 11, wherein
an energy difference between an energy level at a Highest Occupied Molecular Orbital of the organic material and a conduction band of the metallic oxide is equal to or greater than 0.2 eV.

18. The method according to claim 11, wherein
the first electrode and the second electrode are each a metal electrode formed of Au.

19. The method according to claim 11, wherein:
the organic material is C8-benzothienobenzothiophene;
the metallic oxide is molybdenum trioxide; and
a ratio between a vapor deposition rate of the C8-benzothienobenzothiophene and a vapor deposition rate of the molybdenum trioxide is 100:3.

20. The method according to claim 11, wherein
the organic material is pentacene.
